(19) United States
(12) Patent Application Publication
(10) Pub. No.: US 2013/0081696 A1
(43) Pub. Date: Apr. 4, 2013

(54) PACKAGING MATERIAL FOR SOLAR CELL MODULE AND USES THEREOF

(71) Applicants: Tsun-Min HSU, Kaohsiung (TW); Yi-Chung Shih, Kaohsiung (TW); Meng-Tso Chen, Kaohsiung (TW)

(72) Inventors: Tsun-Min HSU, Kaohsiung (TW); Yi-Chung Shih, Kaohsiung (TW); Meng-Tso Chen, Kaohsiung (TW)

(73) Assignee: ETERNAL CHEMICAL CO., LTD.

(21) Appl. No.: 13/598,697

(22) Filed: Aug. 30, 2012

(30) Foreign Application Priority Data
Sep. 30, 2011 (TW) 100135800

(51) Int. Cl. H01L 31/0203; B32B 27/18; B32B 27/08

(52) U.S. Cl. 136/259; 428/421; 428/422; 428/412

(57) ABSTRACT

A packaging material for a solar cell module is provided, which includes a substrate and at least one fluoro-containing coating layer, where the fluoro-containing coating layer includes: (a) a fluoro resin, including a homopolymer or a copolymer formed with a fluoro olefin monomer selected from the group consisting of monofluoroethylene, vinylidene fluoride, chlorotrifluoroethylene, tetrafluoroethylene, hexafluoropropylene, and a combination thereof; and (b) an adhesion promoter of the formula R¹Si(R²)₃ wherein R¹ and R² are as defined in the specification. A solar cell module having the packaging material is further provided.

### BACKGROUND OF THE INVENTION

1. Field of the Invention

The present invention relates to a packaging material for a solar cell module and a solar cell module having said packaging material.

2. Description of the Related Art

Due to the increasingly serious environmental problems such as energy shortage and greenhouse effect, all countries are actively involved in development of various potential alternative energy sources at present, and among which, solar power has attracted great interests in all industries.

As shown in FIG. 1, a solar cell module is generally formed by a transparent front sheet 11 (which is generally a glass sheet), a solar unit 13 contained in an encapsulation material layer 12, and a back sheet 14.

The back sheet 14 functions to protect the solar cell module against environmental damages, and provides electrical insulation properties and aesthetic effects. In order to avoid deterioration of the solar cell module due to contact with moisture, oxygen, or UV light in the environment, the back sheet needs to have good moisture and air barrier properties and good UV resistance. Furthermore, the back sheet 14 is required to be effectively and firmly adhered to the encapsulation material layer 12 for a long period of time, and thus required to have a good adhesion to an encapsulation material (for example, ethylene vinyl acetate (EVA) copolymer) of the encapsulation material layer 12.

The commonly used back sheet material in this field has been a metal substrate or a glass material. Recently, a plastic substrate (for example, a polyester substrate) has gradually replaced metal substrate due to the advantages of being light weight and relatively low manufacturing cost. However, plastic substrate is susceptible to environmental influence and can be easily degraded, so a fluoro-containing polymer having good moisture and air barrier properties and good anti-UV properties, as well as particularly excellent mechanical strength and electrical insulation properties, is employed as a protection layer of the plastic substrate in this field. At present, as a commercially available plastic substrate back sheet having a fluoro-containing polymer protection layer, a laminated film composite sheet having a tri-layer structure of Tedlar®/polyester/Tedlar® is very popular, which has excellent mechanical strength, light stability, chemical resistance, and weather resistance. However, in the fabrication of the multi-layer back sheet, a fluoro-containing polymer needs to be first fabricated into a film, and then laminated to a plastic substrate. Therefore, additional process apparatuses are required, and the problem of high manufacturing cost occurs.

U.S. Pat. No. 7,553,540 discloses that a fluoro-containing polymer coating is prepared by blending a homopolymer or a copolymer of fluoroethylene and vinylidene fluoride and an adhesive polymer having a functional group such as a carboxyl or sulfo group, and a function group capable of reacting with the adhesive polymer is introduced into a plastic substrate, to improve the adhesion force between the fluoro-containing polymer and the substrate. While this method is feasible to apply a fluoro-containing polymer coating onto a plastic substrate, in place of the conventionally known technology of laminating the fluoro-containing polymer film and the substrate, the method is only applicable to a specific substrate, or alternatively the substrate needs to be subjected to surface treatment first, so that the surface of the substrate has the desired functional groups.

In addition, the adhesion force is generally poor when the back sheet having the fluoro-containing polymer is attached to encapsulation material (for example, EVA), due to the poor wettability of the fluoro-containing polymer. Therefore, before attachment, the back sheet needs to be subjected to surface treatment or an adhesive layer needs to be additionally applied on the surface of the back sheet. For example, TW 201034850 discloses that a coating layer formed with one or more acrylic polymers or one or more fluoropolymers is used as the back sheet material, in which a primer is used, so that the back sheet is firmly adhered to the EVA layer. TW 201007961 discloses a tertiary copolymer coating layer containing chlorotrifluoroethylene (CTFE), to which an adhesive layer may be further added to improve the adhesion with the EVA layer. Because the need to use the primer or the additional adhesive layer exists in prior art, the problems of troublesome process and high process cost still exist.

### SUMMARY OF THE INVENTION

Given the above, the inventors of the present invention finds, after extensive research and repeated experimentation, a novel packaging material for a solar cell module, whereby the problems above-described can be effectively solved.

A main objective of the present invention is to provide a packaging material for a solar cell module, which can be directly thermal-laminated to an EVA layer and have an excellent adhesion strength.

In order to achieve the above objective, the present invention provides a packaging material for a solar cell module, which includes a substrate and at least one fluoro-containing coating layer, where the fluoro-containing coating layer includes:
(a) a fluoro resin, comprising a homopolymer or a copolymer formed from a fluoro olefin monomer selected from the group consisting of monofluoroethylene, vinylidene fluoride, chlorotrifluoroethylene, tetrafluoroethylene, hexafluoropropylene, and a combination thereof; and
(b) an adhesion promoter of the formula:

R¹Si(R²)₃,

where R¹ is an organic group having a terminal amino, isocyanate group, epoxy group, vinyl or (meth)acryloxy, R² is each independently selected from the group consisting of a linear or branched C₁₋₄ alkyl, a linear or branched C₁₋₄ alkoxy, and hydroxyl.

The present invention further provides a solar cell module having the packaging material according to the invention. The solar cell module includes a transparent front sheet, a back sheet, an encapsulation material layer located between the transparent front sheet and the back sheet, and one or more solar cell units contained in the encapsulation material layer, wherein at least one of the transparent front sheet, and back sheet contain the above-mentioned packaging material.

The present invention has the following beneficial effects. The packaging material of the present invention has a special fluoro-containing coating layer, which has an excellent adhesion strength with EVA and thus can be directly attached to EVA, eliminating a prior treatment or the use of an additional adhesive layer, so as to simplify the process steps and lower the cost. Moreover, since the packaging material according to the present invention has an excellent adhesion strength with EVA encapsulation material layer, the possible release of the back sheet from the solar cell module due to long time exposure to the environment can be avoided, thereby extending the service life of the solar cell module.

### BRIEF DESCRIPTION OF THE DRAWINGS

FIG. 1 is a schematic view of a solar cell module.

FIG. 2 is a schematic view of a peeling strength test method.

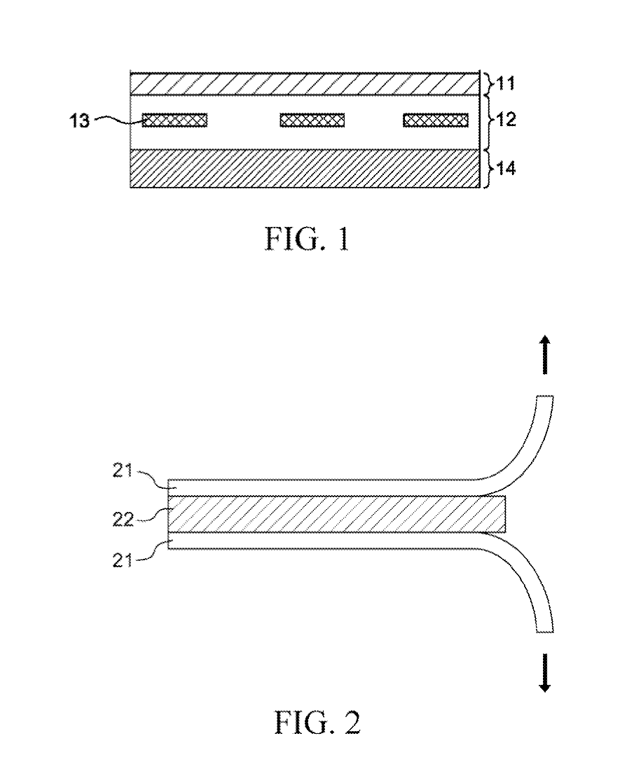

### DETAILED DESCRIPTION OF THE INVENTION

The substrate suitable for use in the present invention may be any substrate known to persons of ordinary skill in the art, and preferably a plastic substrate. The plastic substrate is not particularly limited, and is well known to persons of ordinary skill in the art, which includes, for example, but is not limited to, a polyester resin such as polyethylene terephthalate (PET) or polyethylene naphthalate (PEN); a polyacrylate resin such as polymethyl methacrylate (PMMA); a polyolefin resin such as polyethylene (PE) or polypropylene (PP); a polycycloolefin resin; a polyamide resin such as Nylon 6, Nylon 66 or MXD Nylon (m-xylenediamine/adipic acid copolymer); a polyimide resin; a polycarbonate resin; a polyurethane resin; polyvinyl chloride (PVC); triacetyl cellulose (TAC); polylactic acid; a substituted olefin polymer such as polyvinyl acetate or polyvinyl alcohol; a copolymer resin such as EVA, ethylene/vinyl alcohol copolymer, or ethylene/tetrafluoroethylene copolymer; or a combination thereof, of which the polyester resin, polyacrylate resin, polyolefin resin, polycycloolefin resin, polyimide resin, polyamide resin, polycarbonate resin, polyurethane resin, polyvinyl chloride, TAC, and polylactic acid or the combination thereof are preferred; and polyethylene terephthalate is more preferred. The thickness of the substrate is not particularly limited, and is generally about 15 μm to about 300 μm depending on the requirement of a target product.

The fluoro resin used in the present invention provides the advantage of good weather resistance, and comprises a homopolymer or a copolymer formed from a fluoro olefin monomer selected from the group consisting of monofluoroethylene, vinylidene fluoride, chlorotrifluoroethylene, tetrafluoroethylene, hexafluoropropylene, and a combination thereof, preferably a copolymer formed from a fluoro olefin monomer selected from the group consisting of chlorotrifluoroethylene, tetrafluoroethylene, and a combination thereof, and more preferably a copolymer of chlorotrifluoroethylene.

For example, the fluoro resin used in the present invention may include a copolymer formed with a monomer selected from the group consisting of chlorotrifluoroethylene, tetrafluoroethylene, a vinyl alkyl ether, a vinyl alkanoate and a combination thereof. According to a preferred embodiment of the present invention, the fluoro resin used in the present invention includes a copolymer formed with chlorotrifluoroethylene and a vinyl alkyl ether monomer. When chlorotrifluoroethylene and the vinyl alkyl ether are used as the polymerization units, an alternating copolymer (A-B-A-B) can be easily formed, which is beneficial to the control of the obtained fluoro resin to have a high fluorine content and good, physicochemical properties. According to the present invention, the molar ratio of the fluoro olefin monomer to the vinyl alkyl ether monomer is preferably in the range of 3:1 to 1:3 and more preferably in the range of 2:1 to 1:2.

The vinyl alkyl ether monomer used in the present invention is selected from the group consisting of a vinyl linear alkyl ether monomer, a vinyl branched alkyl ether monomer, a vinyl cycloalkyl ether monomer, a vinyl hydroxyalkyl ether monomer, and a combination thereof, and preferably the alkyl in the vinyl alkyl ether is a C₂₋₁₈ alkyl.

According to the present invention, the amount of the fluoro resin is about 20 wt % to about 95 wt %, preferably about 30 wt % to about 85%, based on the total weight of the solids content of the fluoro-containing coating layer.

Previously, due to the poor adhesion strength between the fluoro resin and the encapsulation material, such as ethylene-vinyl acetate (Ethylene Vinyl Acetate, EVA), the surface of the packaging material of fluoro resin needs to be modified with a primer, or an adhesion layer is additionally applied to the surface of the packaging material before the packaging material is laminated to EVA. The inventors of the present invention find that addition of a specific adhesion promoter to the fluoro-containing coating layer can generate a peeling strength greater than 40 N/cm (about 4 kgf/cm) between the fluoro-containing coating layer of the packaging material and the encapsulation material of the solar cell module, thereby overcoming the disadvantage of poor adhesion force between the conventional fluoro resin and EVA, and effectively simplifying the process.

The adhesion promoter used in the present invention has the formula below:

R¹Si(R²)₃,

where R¹ is an organic group having a terminal amino, isocyanate group, epoxy group, vinyl, or (meth)acryloxy, and R² is each independently selected from the group consisting of a linear or branched C₁₋₄ alkyl, a linear or branched C₁₋₄ alkoxy, and hydroxyl.

R¹ is preferably selected from the group consisting of:

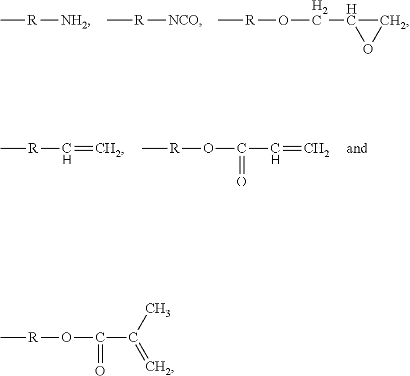

where R is a covalent bond, a linear or branched C₁₋₄ alkylene, or a phenylene optionally substituted with 1 to 3 substituents independently selected from a linear or branched C₁₋₄ alkyl.

R² is preferably each independently selected from the group consisting of methoxy, ethoxy, propoxy, methyl, ethyl, and propyl.

Specific examples of the adhesion promoter include, but are not limited to:

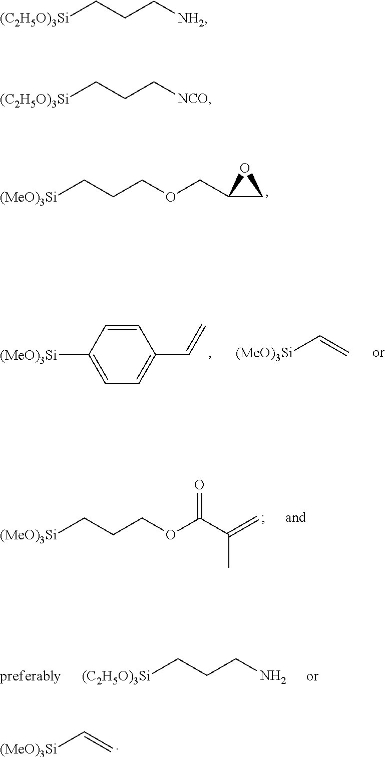

The commercially available adhesion promoter useful in the present invention includes, but is not limited to, substances manufactured by Topco Scientific Co., Ltd. under the trade name KBE-903, KBM-1003, KBM-1403, KBM-403, KBE-9007 or KBM-503.

According to the present invention, the content of the adhesion promoter is about 0.5 wt % to about 15 wt %, and preferably about 1 wt % to about 9 wt %, based on the total weight of the solids content of the fluoro-containing coating layer. If the content of the adhesion promoter is overly less, the operation can be not easy and the adhesion force cannot be effectively improved; and if the content of the adhesion promoter is overly high, the storage stability of the formulated coating could be poor, and the quality and the service life of the fabricated coating layer could be influenced.

The fluoro-containing coating layer of the present invention may include any additive generally known to persons of ordinary skill in the art as desired, which includes, for example, but is not limited to, a colorant, a filler, a curing agent, a curing promoter, a UV absorbent, an anti-static agent, a matting agent, a stabilizer, a cooling aid or an antiflooding agent.

The addition of the colorant in the fluoro-containing coating layer has the effect of improving the aesthetics of the packaging material, and reflecting the light, thereby improving the light use efficiency. The colorant useful in the present invention can be a pigment, and the type thereof is well known to persons of ordinary skill in the art, which includes, for example, but is not limited to, titanium dioxide, calcium carbonate, carbon black, iron oxide, chrome pigments, and titanium black, with titanium dioxide being preferred.

According to an embodiment of the present invention, the fluoro-containing coating layer may further include a curing agent, which functions to generate an intermolecular chemical bond with the fluoro resin, resulting in crosslinking. The curing agent useful in the present invention is well known to persons of ordinary skill in the art, which includes, for example, but is not limited to, polyisocyanate. Therefore, if present, the amount of the curing agent added is about 1% to about 30%, and preferably about 3% to about 20%, based on the total weight of the solids content of the fluoro-containing coating layer.

The packaging material of the present invention includes a substrate, and the substrate includes a fluoro-containing coating layer on at least one side. According to an embodiment of the present invention, the substrate has a fluoro-containing coating layer on one side. According to another embodiment of the present invention, the substrate has fluoro-containing coating layers on both sides.

The packaging material of the present invention may be fabricated by applying the fluoro-containing coating layer to the substrate, by using any method well known to persons of ordinary skill in the art. For example, a suitable coating may be coated onto the substrate, and then dried to form the fluoro-containing coating layer. The coating method includes, for example, but is not limited to knife coating, roller coating, micro gravure coating, flow coating, dip coating, spray coating, slot die coating, spin coating, and curtain coating, or other generally known methods, or a combination thereof.

For example, the packaging material according to an embodiment of the present invention may be prepared through the following steps:

(a) mixing the fluoro resin, the adhesion promoter and an optional additive in a solvent, to form a coating;

(b) coating the coating obtained in Step (a) onto the substrate, and drying it by heating; and

(c) then conducting curing, to form the fluoro-containing coating layer.

The solvent used in Step (a) is not particularly limited, and may be any suitable organic solvent known to persons of ordinary skilled in the art, which can be, for example, but is not limited to, an alkane, an aromatic hydrocarbon, a ketone, an ester, an ether alcohol or a mixture thereof.

The viscosity of the coating can be adjusted to be in a range suitable for operation by adding the organic solvent to the coating. The content of the organic solvent is not particularly limited, and may be adjusted according to practical conditions and requirements, so that the coating has a desired viscosity. According to an embodiment of the present invention, a suitable amount of solvent may be added to control the solids content of the coating in the range of about 10 wt % to about 70 wt % for convenience of operation.

The alkane solvent useful in the present invention includes, for example, but is not limited to, n-hexane, n-heptane, isoheptane or a mixture thereof.

The aromatic hydrocarbon solvent useful in the present invention includes, for example, but is not limited to, benzene, toluene, xylene or a mixture thereof.

The ketone solvent useful in the present invention includes, for example, but is not limited to, methyl ethyl ketone (MEK), acetone, methyl isobutyl ketone, cyclohexanone, 4-hydroxy-4-methyl-2-pentanone or a mixture thereof.

The ester solvent useful in the present invention includes, for example, but is not limited to, isobutyl acetate (IBAC), ethyl acetate (EAC), butyl acetate (BAC), ethyl formate, methyl acetate, ethoxyethyl acetate, ethoxypropyl acetate, ethyl isobutyrate, propylene glycol monomethyl ether acetate, pentyl acetate or a mixture thereof.

The ether alcohol solvent useful in the present invention includes, for example, but is not limited to, ethylene glycol butyl ether (BCS), ethylene glycol ethyl ether acetate (CAC), ethylene glycol ethyl ether (ECS), propylene glycol methyl ether, propylene glycol methyl ether acetate (PMA), propylene glycol monomethyl ether propionate (PMP), butylene glycol methyl ether (DBE) or a mixture thereof.

The heating temperature and time involved in the above-mentioned Step (b) are not particularly limited, provided that the main purpose of removing the solvent can be achieved. For example, the heating can be conducted at a temperature of 80° C. to 180° C. for 30 sec to 10 min. The curing time in the above-mentioned Step (c) is not particularly limited, and may be, for example, about 1 day to about 3 days.

The thickness of the obtained coating layer is not particularly limited, and the monolayer thickness preferably is in the range of 1 μm to 50 μm and more preferably is in the range of 5 μm to 30 μm.

The packaging material of the present invention may be fabricated through the steps of directly applying the coating onto the substrate, and drying and curing the coating. Therefore, compared with the prior art in which the fluoro resin thin sheet needs to be first fabricated and then attached to the substrate, the packaging material of the present invention has the advantages that the process is convenient and the cost is low.

The present invention further provides a solar cell module having the packaging material according to the invention. The solar cell module is, for example, but not limited to, a crystalline silicon solar cell module or a thin film solar cell module. The solar cell module has a structure well-known to persons of ordinary skill in the art. The crystalline silicon solar cell module may include a transparent front sheet, a back sheet, an encapsulation material layer located between the transparent front sheet and the back sheet, and one or more solar cell units contained in the encapsulation material layer. The packaging material of the present invention may be directly used as the front sheet or the back sheet of the solar cell module, and thermal-laminated to the encapsulation material layer.

According to an embodiment of the present invention, the solar cell module of the present invention includes a transparent front sheet, a back sheet, an encapsulation material layer located between the transparent front sheet and the back sheet, and one or more solar cell units contained in the encapsulation material layer, where at least one of the transparent front sheet and back sheet includes the packaging material of the present invention.

Any lamination method well known to persons of ordinary skill in the art can be used to attach the packaging material of the present invention to the encapsulation material layer. For example, the packaging material of the present invention can be attached to the encapsulation material layer through vacuum lamination, and the vacuum lamination conditions are not particularly limited. For example, when using EVA as the encapsulation material layer, the lamination may be completed by pressurizing for 2 to 20 min at a temperature of 130° C. to 180° C. while a bottom cover of a laminator is adjusted to be at a vacuum level of 20 Pa to 100 Pa and a top cover is adjusted to be under a pressure of 20 kPa to 100 kPa. The pressurization step may be completed in one or more stages.

The packaging material of the present invention has a good adhesion force with the EVA encapsulation material layer, and thus can be directly laminated to the EVA encapsulation material layer, without the need of a pre-treatment step of coating a primer onto the surface of the thin sheet or corona discharge or using an additional adhesive layer.

The present invention will be further described with reference to the examples below; however the scope of the present invention is not limited thereto. The scope of the present invention is based on what is defined by the claims. It is apparent to persons skilled in the art that various variations, modifications, or replacements may be made to the present invention without departing from the spirit and scope of the present invention.

The abbreviations used herein are defined as follows:

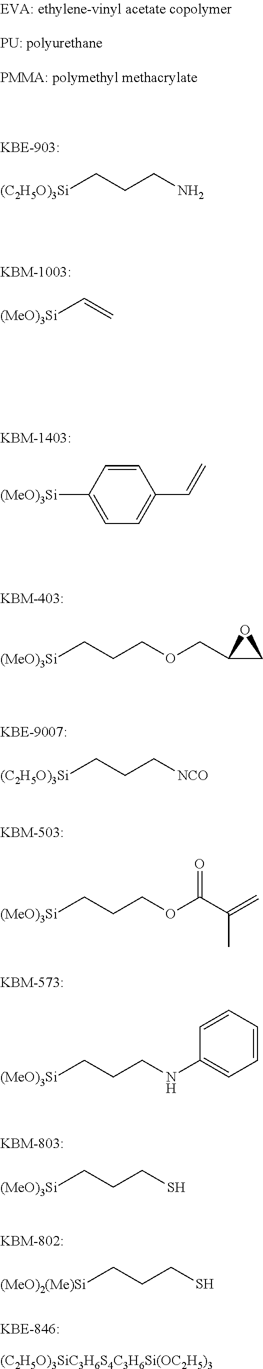

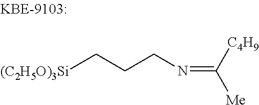

### EXAMPLE 1

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 29.8 g toluene and 0.44 g of an adhesion promoter (KBE-903 provided by Topco Scientific Co., Ltd., which had a solids content of 100%) were sequentially added with stirring at a high speed, and finally 2.3 g of a curing agent (Desmodur 3390 provided by Bayer Corporation, which had a solids content of about 75%, and was an isocyanate curing agent) was added, to prepare about 46.5 g of a coating having a solids content of about 22.7 wt %, in which the content of the adhesion promoter was about 4.2 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 min at 140° C., and cured for 2 days in an oven at 70° C. to obtain a packaging material having a thickness of about 20 μm and having a fluoro-containing coating layer.

### EXAMPLE 2

The steps of Example 1 were repeated, except that the adhesion promoter was replaced by KBM-1003 (provided by Topco Scientific Co., Ltd., and having a solids content of 100%).

### EXAMPLE 3

The steps of Example 1 were repeated, except that the adhesion promoter was replaced by KBM-1403 (provided, by Topco Scientific Co., Ltd., and having a solids content of 100%).

### EXAMPLE 4

The steps of Example 1 were repeated, except that the adhesion promoter was replaced by KBM-403 (provided by Topco Scientific Co., Ltd, and having a solids content of 100%).

### EXAMPLE 5

The steps of Example 1 were repeated, except that the adhesion promoter was replaced by KBM-9007 (provided by Topco Scientific Co., Ltd., and having a solids content of 100%).

### EXAMPLE 6

The steps of Example 1 were repeated, except that the adhesion promoter was replaced by KBM-503 (provided by Topco Scientific Co., Ltd., and having a solids content of 100%).

### EXAMPLE 7

The steps of Example 1 were repeated, except that the amounts of toluene, the adhesion promoter, and the curing agent were respectively 28.3 g, 0.08 g, and 2.0 g, to prepare about 44.38 g of a coaling having a solids content of about 22.5 wt %, in which the content of the adhesion promoter was about 0.8 wt %, based on the total weight of the solids content of the coating.

### EXAMPLE 8

The steps of Example 1 were repeated, except that the amounts of toluene, the adhesion promoter, and the curing agent were respectively 28.7 g, 0.18 g, and 2.1 g, to prepare about 44.98 g of a coating having a solids content of about 20.3 wt %, in which the content of the adhesion promoter was about 1.8 wt %, based on the total weight of the solids content of the coating.

### EXAMPLE 9

The steps of Example 1 were repeated, except that the amounts of toluene, the adhesion promoter, and the curing agent were respectively 29.4 g, 0.36 g, and 2.22 g, to prepare about 45.98 g of a coating having a solids content of about 22.7 wt %, in which the content of the adhesion promoter was about 3.6 wt %, based on the total weight of the solids content of the coating.

### EXAMPLE 10

The steps of Example 1 were repeated, except that the amounts of toluene, the adhesion promoter, and the curing agent were respectively 30.8 g, 0.68 g, and 2.54 g, to prepare about 48.02 g of a coating having a solids content of about 22.9 wt %, in which the content of the adhesion promoter was about 6.2 wt %, based on the total weight of the solids content of the coating.

### EXAMPLE 11

The steps of Example 1 were repeated, except that the amounts of toluene, the adhesion promoter, and the curing agent were respectively 31.68 g, 0.93 g, and 2.8 g, to prepare about 49.41 g of a coating having a solids content of about 23.1 wt %, in which the content of the adhesion promoter was about 8.1 wt %, based on the total weight of the solids content of the coating.

### EXAMPLE 12

37.66 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 36.75 g toluene, 22.6 g titanium dioxide (R-902, provided by DuPont Company and having a solids content of 100%), and 3.2 g of an adhesion promoter (KBE-903 provided by Topco Scientific Co., Ltd., which, had a solids content of 100%) were sequentially added with stirring at a high speed, and finally 6.85 g of a curing agent (Desmodur 3390 provided by Bayer Corporation, which had a solids content of about 75%, and was an isocyanate curing agent) was added, to prepare about 107 g of a coating having a solids content of about 50%, in which the content of the adhesion promoter was about 6.0 wt %, based on the total weight of the solids content of the coating, and the content of the titanium dioxide was about 42 wt %, based on the total weight of the solids content of the coating.

The coating was coated onto a polyethylene terephthalate film (CH885 provided by Nanya Corporation, which had a thickness of 250 μm, and was a polyethylene terephthalate film) with an RDS coating rod #35, dried for 1 min at 140° C., and cured for 2 days in an oven at 70° C., to obtain a package material having a thickness of about 25 μm with a fluoro-containing coating layer.

### COMPARATIVE EXAMPLE 1

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 28 g toluene and 1.9 g of a curing agent (Desmodur 3390 provided by Bayer Corporation, which had a solids content of about 75%, and was an isocyanate curing agent) were sequentially added with stirring at a high speed, to prepare about 43.9 g of a coating having a solids content of about 22.4 %.

The coating was coated onto a polyethylene terephthalate film (CH885 provided by Nanya Corporation, which had a thickness of 250 μm, and was a polyethylene terephthalate film) with an RDS coating rod #50, dried for 1 min at 140° C., and cured for 2 days in an oven at 70° C., to obtain a package material having a thickness of about 20 μm with a fluoro-containing coating layer.

### COMPARATIVE EXAMPLE 2

90 g of toluene was added in a plastic flask, to which 10 g of PU particles (AH-810L provided by Taiwan Sheen Soon Co., Ltd.) was added with stirring at a high speed and completely dissolved, to prepare a 10% PU-toluene solution.

14 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to another plastic flask, to which 23.5 g toluene and 9.2 g of the above-mentioned PU-toluene solution were sequentially added with stirring at a high speed, and finally 1.9 g of a curing agent (Desmodur 3390 provided by Bayer Corporation, which had a solids content of about 75%, and was an isocyanate curing agent) was added, to prepare about 48.6 g of a coating having a solids content of about 22.1%, in which the content of PU was about 8.6 wt %, based on the total weight of the solids content of the coating.

The coating was coated onto a PET film (CH885 provided by Nanya Corporation, which had a thickness of 250 μm, and was a polyethylene terephthalate film) with an RDS coating rod #50, dried for 1 min at 140° C., and cured for 2 days in an oven at 70° C., to obtain a thin sheet having a thickness of about 20 μm and having a fluoro-containing coating layer.

### COMPARATIVE EXAMPLE 3

90 g of toluene was added in a plastic flask, to which 10 g of EVA particles (UE-654 provided by USI Corporation) was added with stirring at a high speed and completely dissolved, to prepare a 10% EVA-toluene solution.

The steps of Comparative Example 2 were repeated, except that the above-mentioned EVA-toluene solution was used instead of the PU-toluene solution.

### COMPARATIVE EXAMPLE 4

90 g of toluene was added in a plastic flask, to which 10 g of a polyester resin (Eterkyd 5054 solid particles provided by Eternal Chemical Co., Ltd.) was added with stirring at a high speed and completely dissolved, to prepare a 10% polyester resin-toluene solution.

The steps of Comparative Example 2 were repeated, except that the above-mentioned polyester resin-toluene solution was used instead of the PU-toluene solution.

### COMPARATIVE EXAMPLE 5

90 g of toluene was added in a plastic flask, to which 10 g of a poly(methyl methacrylate) (ETERAC 715H-18 provided by Eternal Chemical Co., Ltd. and having a molecular weight of 180,000 and Tg=118° C.) was added with stirring at a high speed and completely dissolved, to prepare a 10% poly(methyl methacrylate) resin-toluene solution.

The steps of Comparative Example 2 were repeated, except that the above-mentioned poly(methyl methacrylate) resin-toluene solution was used instead of the PU-toluene solution.

### COMPARATIVE EXAMPLE 6

The steps of Example 1 were repeated, except that the adhesion promoter was replaced by KBM-573 (provided by Topco Scientific Co., Ltd., and having a solids content of 100%).

### COMPARATIVE EXAMPLE 7

The steps of Example 1 were repeated, except that the adhesion promoter was replaced by KBM-803 (provided by Topco Scientific Co., Ltd., and having a solids content of 100%).

### COMPARATIVE EXAMPLE 8

The steps of Example 1 were repeated, except that the adhesion promoter was replaced by KBM-802 (provided by Topco Scientific Co., Ltd., and having a solids content of 100%).

### COMPARATIVE EXAMPLE 9

The steps of Example 1 were repeated, except that the adhesion promoter was replaced by KBM-846 (provided by Topco Scientific Co., Ltd., and having a solids content of 100%).

### COMPARATIVE EXAMPLE 10

The steps of Example 1 were repeated, except that the adhesion promoter was replaced by KBM-9103 (provided by Topco Scientific Co., Ltd., and having a solids content of 100%).

### COMPARATIVE EXAMPLE 11

37.66 g of a fluoro resin (Eterflon 4101-60 provided by Eternal Chemical Co., Ltd., which had a solids content of 60%, and was a copolymer resin of chlorotrifluoroethylene and a vinyl alkyl ether) was added to a plastic flask, to which 34.63 g toluene and 22.6 g titanium dioxide (R-902, provided by DuPont Company and having a solids content of 100%) were sequentially added with stirring at a high speed, and finally 5.11 g of a curing agent (Desmodur 3390 provided by Bayer Corporation, which had a solids content of about 75%, and was an isocyanate curing agent) was added, to prepare about 100 g of a coating having a solids content of about 49%, in which the content of the titanium dioxide was about 46 wt %, based on the total weight of the solids content of the coating.

The coating was coated onto a polyethylene terephthalate film (CH885 provided by Nanya Corporation, which had a thickness of 250 μm, and was a polyethylene terephthalate film) with an RDS coating rod #35, dried for 1 min at 140° C., and cured for 2 days in an oven at 70° C., to obtain a package material having a thickness of about 25 μm with a fluoro-containing coating layer.

The test methods involved in the claimed invention are as follows.

<Test Method of Peeling Strength between the Thin Sheet and the EVA Film>:

### 1. Fabrication of Test Piece:

Two equivalent thin sheets prepared in the examples or comparative examples below are cut into pieces of 15 cm×10.5 cm. The two pieces are overlapped with the long edge (15 cm) in the top-down direction, the short edge (10.5 cm) in the left-right direction, and the coating layers opposite to each other. Then, a tape (MY1GA-19 mm×33 m, manufactured by Symbio Co., Ltd.) of 3.5 cm×10.5 cm is respectively attached to an upper end of the coating layer, and an EVA film (model EV624-EVASKY, manufactured by Bridgestone Corporation) of 13 cm×10.5 cm is sandwiched between the two pieces having the tape, so that the upper ends of the two piece coating layers do not directly contact EVA due to the presence of the tape, which is convenient for the subsequent peeling strength test.

The fabricated test piece is placed on a laminator (model SML-0808, Chinup Co., Ltd.), and then subjected to a lamination process in which vacuum deaeration (with the top cover pressure being 70 kpa, and a bottom cover pressure being 0 kpa) is conducted for 8 min on a heating plate at a temperature of 150±10° C.; then the top cover is pressurized, with a pressure of 20 kPa for 27 sec in a first stage, a pressure of 40 kPa for 10 sec in a second stage, a pressure of 80 kPa for 6 sec in a third stage, and finally, maintained at the pressure of 80 kPa applied in the third stage for 8 min; and taken out after being cooled to room temperature for EVA peeling strength test.

### 2. EVA Peeling Strength Test

The test piece after lamination to the EVA film is cut into test strips of 15 cm×1 cm along the long edge, and the portion pre-attached with the tape is torn into two pieces, which are respectively clipped into two jig heads of a micro-computer tensile tester (HT-9102, Hung Ta Instrument Co., Ltd., having a highest load of 100 kg), but the EVA layer portion is not clipped by the jig heads; and is 1 cm away from the two jig heads. The peeling strength test is conducted by oppositely drawing at an angle of 180 degrees in the top to down direction. FIG. 2 is a schematic view of the peeling strength test method, in which 21 is a thin sheet fabricated in the examples or comparative examples, and 22 is the EVA film.

The test is carried out following the ASTM D1876 standard test method. Drawing of the two jig heads is stopped till the distance therebetween is greater than 12 cm, and a corresponding peeling strength value is determined. The drawing rate in the test is 10 cm/min, and the test is passed in case of a peeling strength value of 4 kgf/cm or higher. The results are recorded in Tables 1 to 4.

TABLE 1
Influence of using different adhesion promoters on the peeling
strength between the packaging material and EVA

| | | Comparative | Comparative | Comparative | Comparative | Comparative |
|---|---|---|---|---|---|---|
| | Example 1 | Example 1 | Example 2 | Example 3 | Example 4 | Example 5 |
| Adhesion | KBE-903 | — | PU | EVA | polyester | PMMA |
| promoter | | | | | | |
| Content | 4.2 wt % | 0 wt % | 8.6 wt % | 8.6 wt % | 8.6 wt % | 8.6 wt % |
| Peeling | 7.0 | 2.7 | 1.4 | 0.3 | 1.5 | 2.0 |
| strength | | | | | | |
| kgf/cm | | | | | | |

TABLE 2
Influence of using different silicon-containing adhesion promoters
on the peeling strength between the packaging material and EVA

| | Example 1 | Example 2 | Example 3 | Example 4 | Example 5 | Example 6 |
|---|---|---|---|---|---|---|
| Silicon- | KBE-903 | KBM-1003 | KBM-1403 | KBM-403 | KBE-9007 | KBM-503 |
| containing | | | | | | |
| adhesion | | | | | | |
| promoter | | | | | | |
| (4.2 wt %) | | | | | | |
| Peeling | 7.0 | 6.6 | 4.1 | 4.1 | 4.2 | 4.0 |
| strength | | | | | | |
| kgf/cm | | | | | | |

| | Comparative | Comparative | Comparative | Comparative | Comparative |
|---|---|---|---|---|---|
| | Example 6 | Example 7 | Example 8 | Example 9 | Example 10 |
| Silicon- | KBM-573 | KBM-803 | KBM-802 | KBE-846 | KBE-9103 |
| containing | | | | | |
| adhesion | | | | | |
| promoter | | | | | |
| (4.2 wt %) | | | | | |
| Peeling | 2.9 | 1.5 | 1.7 | 0.3 | 1.9 |
| strength | | | | | |
| kgf/cm | | | | | |

TABLE 3
Influence of the content of adhesion promoters on the peeling
strength between the packaging Material and EVA

| | Example 7 | Example 8 | Example 9 | Example 10 | Example 11 |
|---|---|---|---|---|---|
| KBE-903 | 0.8 wt % | 1.8 wt % | 3.6 wt % | 6.2 wt % | 8.1 wt % |
| Peeling | 4.6 | 6.4 | 6.5 | 8.9 | 10.0 |
| strength | | | | | |
| kgf/cm | | | | | |

TABLE 4
Influence of the addition of an adhesion promoter in the presence of
an additive on the peeling strength between the packaging material and
EVA

| | Example 12 | Comparative Example 11 |
|---|---|---|
| Content of titanium | 42 wt % | 46 wt % |
| dioxide | | |
| Content of KBE-903 | 6 wt % | 0 wt % |
| Peeling strength | 7.7 | 1.1 |
| kgf/cm | | |

It can be seen from the results in Table 1 that in the absence of any adhesion promoter (Comparative Example 1) or adding a polymeric resin as an adhesion promoter (Comparative Examples 2 to 5), the peeling strengths between the resultant packaging material and the EVA layer are less than that required in tensile strength test standard (>4 kgf/cm) in the industry, and the peeling strength between the fluoro-containing coating and the EVA layer cannot be effectively improved. In contrast, the packaging material including the adhesion promoter according to the present invention (Example 1) can enhance the peeling strength with EVA. The results show that if the fluoro-containing coating layer of the packaging materials contains a specific adhesion promoter according to the present invention, it can be directly attached to EVA with an effective increase in the peeling strength between the fluoro-containing coating layer and the EVA layer, without the need of a prior treatment or the use of an additional adhesive layer.

It can be seen from the results in Table 2 that only specific silicon-containing adhesion promoters can improve the peeling strength between the fluoro-containing coating layer and the EVA layer. Examples 1 to 6 used the silane coupling agents with terminal —NH₂, —HCO, epoxy group, vinyl group, and (meth)acryloxy group that can effectively enhance the said peeling strength to the level that meets the required tensile strength test standard (>4 kgf/cm) in the industry. In contrast, the peeling strengths obtained from Comparative Examples 6 to 10 are only in the range from 0.3 kgf/cm to 2.9 kgf/cm, and cannot meet the requirement in the industry.

It can be seen from the results in Table 3 that in the presence of the adhesion promoter according to the present invention, the peeling strength between the fluoro-containing coating layer and the EVA layer can be improved, resulting in an effective increase in the adhesion strength of the fluoro-containing coating layer to the EVA layer; and the more the adhesion promoter is used, the higher the peeling strength can be obtained.

It can be seen from the results in Table 4 that in the absence of an additive (titanium dioxide), the adhesion promoter according to the present invention can still enhance the peeling strength between the fluoro-containing coating layer and the EVA layer.

What is claimed is:

1. A packaging material for a solar cell module, comprising a substrate and at least one fluoro-containing coating layer, wherein the fluoro-containing coating layer comprises:
(a) a fluoro resin, comprising a homopolymer or a copolymer formed with a fluoro olefin monomer selected from the group consisting of monofluoroethylene, vinylidene fluoride chlorotrifluoroethylene, tetrafluoroethylene, hexafluoropropylene, and a combination thereof; and
(b) an adhesion promoter of the formula:
R¹Si(R²)₃,
wherein R¹ is an organic group having a terminal amino, isocyanate group, epoxy group, vinyl or (meth)acryloxy, R² is each independently selected from the group consisting of a linear or branched C₁₋₄ alkyl, a linear or branched C₁₋₄ alkoxy, and hydroxyl.

2. The packaging material according to claim 1, wherein the fluoro resin comprises a homopolymer or a copolymer formed with a fluoro olefin monomer selected from the group consisting of chlorotrifluoroethylene, tetrafluoroethylene, and a combination thereof.

3. The packaging material according to claim 1, wherein the fluoro resin comprises a copolymer formed with chlorotrifluoroethylene and a vinyl alkyl ether monomer.

4. The packaging material according to claim 3, wherein the vinyl alkyl ether monomer is selected from the group consisting of a vinyl linear alkyl ether monomer, a vinyl branched alkyl ether monomer, a vinyl cycloalkyl ether monomer, a vinyl hydroxyalkyl ether monomer, and a combination thereof.

5. The packaging material according to claim 1, wherein the fluoro resin is present in an amount of 20% to 95%, based on the total weight of the solids content of the fluoro-containing coating layer.

6. The packaging material according to claim 1, wherein the adhesion promoter is present in an amount of 0.5 wt % to 15 wt %, based on the total weight of the solids content of the fluoro-containing coating layer.

7. The packaging material according to claim 6, wherein the adhesion promoter is present in an amount of 1 wt % to 9 wt %, based on the total weight of the solids content of the fluoro-containing coating layer.

8. The packaging material according to claim 1, wherein the substrate comprises a polyester resin, a polyacrylate resin, a polyolefin resin, a polycycloolefin resin, a polyamide resin, a polyimide resin, a polycarbonate resin, a polyurethane resin, a polyvinyl chloride, triacetyl cellulose, polylactic acid or a combination thereof.

9. The packaging material according to claim 1, wherein R¹ is a group having the structure below: 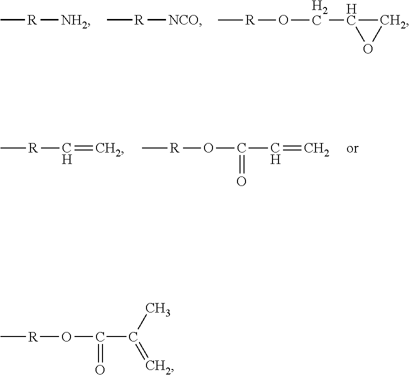
wherein R is a covalent bond, a linear or branched C₁₋₄ alkylene, or a phenylene optionally substituted with 1 to 3 substituents independently selected from a linear or branched C₁₋₄ alkyl.

10. The packaging material according to claim 1, wherein R² is each independently selected from the group consisting of methoxy, ethoxy, propoxy, methyl, ethyl, and propyl.

11. The packaging material according to claim 9, wherein the adhesion promoter is:

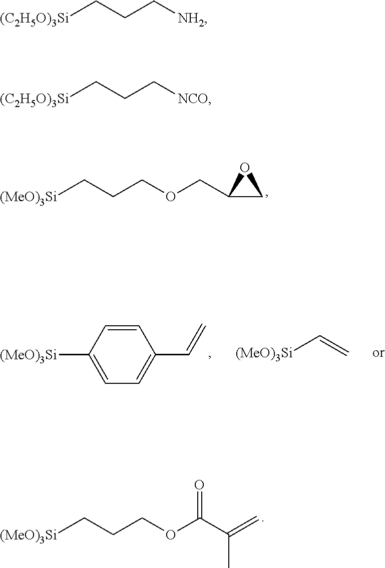

12. A solar cell module, comprising the packaging material according to claim 1.
